(19) United States
(12) Patent Application Publication
(10) Pub. No.: US 2024/0304486 A1
(43) Pub. Date: Sep. 12, 2024

(54) DIFFERENTIAL SUBSTRATE BACKSIDE COOLING

(71) Applicant: Applied Materials, Inc., Santa Clara, CA (US)

(72) Inventors: Yogananda Sarode Vishwanath, Bangalore (IN); Anand Kumar, Bangalore (IN)

(21) Appl. No.: 18/206,443

(22) Filed: Jun. 6, 2023

(30) Foreign Application Priority Data
Mar. 10, 2023 (IN) 202341016046

(51) Int. Cl. H01L 21/683; H01J 37/32; H01L 21/687

(52) U.S. Cl. CPC H01L 21/6833; H01J 37/3244; H01J 37/32724; H01L 21/68757; H01J 2237/334

(57) ABSTRACT

An electrostatic chuck (ESC) having a ceramic body including embedded electrodes and having a first diameter. Three or more regions are defined on a surface and arranged concentrically on the surface, each region includes a retaining ring arranged on the surface and defining an outer edge of the region, and supportive structures arranged on the surface and within the region. The supportive structures are configured to support a surface of a substrate when the substrate is retained by the ESC. The ESC includes conduits formed in the ceramic body and configured to independently introduce a gas into each region through the ceramic body and to the first surface. Each region is configured to retain a corresponding positive gas pressure within the region and the surface of the substrate, and the one or more embedded electrodes are configured to generate a retaining force on the surface of the substrate.

### CROSS-REFERENCE TO RELATED APPLICATIONS

This application claims the benefit of priority under 35 U.S.C. § 119 to Indian Patent Application No. 202341016046, filed on Mar. 10, 2023, the contents of which are hereby incorporated by reference.

### TECHNICAL FIELD

This specification relates to semiconductor systems, processes, and equipment.

### BACKGROUND

Plasma etching can be used in semiconductor processing to fabricate integrated circuits. Integrated circuits can be formed from layer structures including multiple (e.g., two or more) layer compositions. Different etching gas chemistries, e.g., different mixtures of gases, can be used to form a plasma in the processing environment such that a given etching gas chemistry can have increased precision and higher selectivity for a layer composition to be etched. As scaling of integrated circuits continues to move towards smaller features and increased aspect ratios, there is a growing need for precision etching of layer structures.

### SUMMARY

This specification describes technologies for differential substrate backside cooling. These technologies generally involve implementing electrostatic chuck design(s) including multiple design parameters to generate an electrostatic chuck configured for differential substrate backside cooling to yield improved substrate temperature uniformity and tunability during a fabrication process, e.g., during plasma etching.

As used in this specification, a substrate refers to a wafer or another carrier structure, e.g., a glass plate. A wafer can include a semiconductor material, e.g., Silicon, GaAs, InP, or another semiconductor-based wafer material. A wafer can include an insulator material, for example, silicon-on-insulator (SOI), diamond, etc. At times, the substrate includes film(s) formed on a surface of the wafer/carrier structure. The film(s) can be, for example, dielectric, conductive or insulating films. The film(s) can be formed on the surface of the wafer using various deposition techniques, for example, spin-coating, atomic layer deposition (ALD), chemical vapor deposition (CVD), metal-organic chemical vapor deposition (MOCVD), molecular beam epitaxy (MBE) or other similar techniques for forming thin film layers on a wafer or another carrier structure. In some embodiments, the fabrications tools described in this specification are plasma-based etching tools, where etch processes can be performed on the formed layers on the surface of the wafer/carrier structure and/or on the wafer.

In general, one innovative aspect of the subject matter described in this specification can be embodied in an electrostatic chuck (ESC). The ESC includes a ceramic body including one or more embedded electrodes, and a first surface having a first diameter. Three or more regions are defined on the first surface, where the three or more regions are arranged concentrically on the first surface. Each region includes a retaining ring arranged on the first surface and defining an outer edge of the region, and supportive structures arranged on the first surface and within the region, where the supportive structures are configured to support a surface of a substrate when the substrate is retained by the electrostatic chuck. The ESC includes conduits formed in the ceramic body and configured to independently introduce a gas into each of the three or more regions through the ceramic body and to the first surface, where each region of the three or more regions is configured to retain a corresponding positive gas pressure within the region and the surface of the substrate when the substrate is retained by the electrostatic chuck, and where the one or more embedded electrodes are configured to generate a retaining force on the surface of the substrate when the substrate is retained by the electrostatic chuck.

Other embodiments of this aspect include corresponding methods, computer systems, apparatus, and computer programs recorded on one or more computer storage devices.

In general, another innovative aspect of the subject matter described in this specification can be embodied in methods for cooling an electrostatic chuck during plasma processing. The methods include providing a gas through conduits within a ceramic body of the electrostatic chuck to three or more regions defined on a first surface of the ceramic body and configured to retain a positive gas pressure within the region and a surface of a substrate retained by the electrostatic chuck, where the three or more regions are arranged concentrically on the first surface, and where an outer edge of each region of the three or more regions is defined by a respective retaining ring arranged on the first surface. The methods include providing, by one or more electrodes within the ceramic body and arranged with respect to the first surface, a retaining force on the surface of the substrate. Other embodiments of this aspect include corresponding systems, computer systems, apparatus, and computer programs recorded on one or more computer storage devices, each configured to perform the actions of the methods.

In general, another innovative aspect of the subject matter described in this specification can be embodied in a system including a plasma processing chamber enclosing a processing region, a gas source configured to introduce one or more etch gases into the processing region, a plasma source configured to generate a plasma within the processing region using the one or more etch gases introduced into the processing region, and an electrostatic chuck within the plasma processing chamber and configured to retain a substrate in the processing region of the plasma processing chamber during plasma processing. The electrostatic chuck includes a ceramic body including one or more embedded electrodes configured to generate a retaining force on a surface of the substrate when the substrate is retained by the electrostatic chuck, three or more regions defined on a first surface of the ceramic body, where the three or more regions are arranging concentrically on the first surface, each region including a retaining ring arranged on the first surface and defining an outer edge of the region, and conduits formed in the ceramic body and configured to independently introduce a gas into each of the three or more regions through the ceramic body and to the first surface.

The subject matter described in this specification can be implemented in these and other embodiments so as to realize one or more of the following advantages. The electrostatic chuck design system can leverage a model (e.g., machine-learning model) to incorporate different available design parameters to design customized electrostatic chuck solutions that can address chamber-specific temperature non-uniformity across the substrate. Electrostatic chucks providing improved on-substrate temperature uniformity can lead to improved uniformity of etch rates across the substrate and can result in higher fidelity and/or higher yield outcomes for fabricated devices on the substrate. The electrostatic chuck design system can be used to design electrostatic chucks specific to fabrication processes, for example, specific to conductor-film etching process or specific to dielectric-film etching processes, which can address specific non-uniformities arising from the respective processes. The electrostatic chuck design model can be used to design an electrostatic chuck having a threshold density of mesa structures in one or more of the cooling regions, such that the one or more cooling regions use gas-dominated cooling, where the cooling can be dynamically tuned based on a gas pressure introduced into the cooling regions, for example, in response to (or to adjust) real-time process parameters. For example, design considerations can be used to adjust substrate temperature (and resulting etch rate) in real-time. Although the remaining disclosure will identify specific implementations of apparatuses, systems, and methods for etch-based fabrication tools using the disclosed technology, it will be readily understood that the systems and methods are equally applicable to a variety of other fabrication tools and chambers. Accordingly, the technology should not be considered to be so limited as for use with the described etching fabrication tools alone. The disclosure will discuss one possible system and chamber that can be used with the present technology before describing systems and methods or operations of exemplary process sequences according to some embodiments of the present technology. It is to be understood that the technology is not limited to the equipment described, and processes discussed can be performed in any number of processing chambers and systems.

### BRIEF DESCRIPTION OF THE DRAWINGS

FIG. 1 shows a schematic cross-sectional view of an example plasma processing chamber.

FIG. 2 shows an example operating environment for an electrostatic chuck design system.

FIGS. 3A and 3B show various schematic views of an example electrostatic chuck.

FIGS. 4A and 4B show various schematic views of another example electrostatic chuck.

FIGS. 5A and 5B show various schematic views of example electrostatic chucks.

FIG. 6 is an example plot depicting substrate backside cooling theory.

FIG. 7 shows a flow diagram of an example process for an electrostatic chuck.

FIG. 8 shows a flow diagram of an example process for an electrostatic chuck design system.

FIG. 9 is a block diagram of an example generic computing system.

Like reference numbers and designations in the various drawings indicate like elements.

### DETAILED DESCRIPTION

The present specification provides improved methods, systems, and assemblies for an electrostatic chuck configured for differential substrate backside cooling. Embodiments of the present disclosure include electrostatic chuck design(s) including implementing multiple design parameters to generate an electrostatic chuck configured for differential substrate backside cooling to yield improved substrate temperature uniformity and tunability during a fabrication process, e.g., during plasma etching.

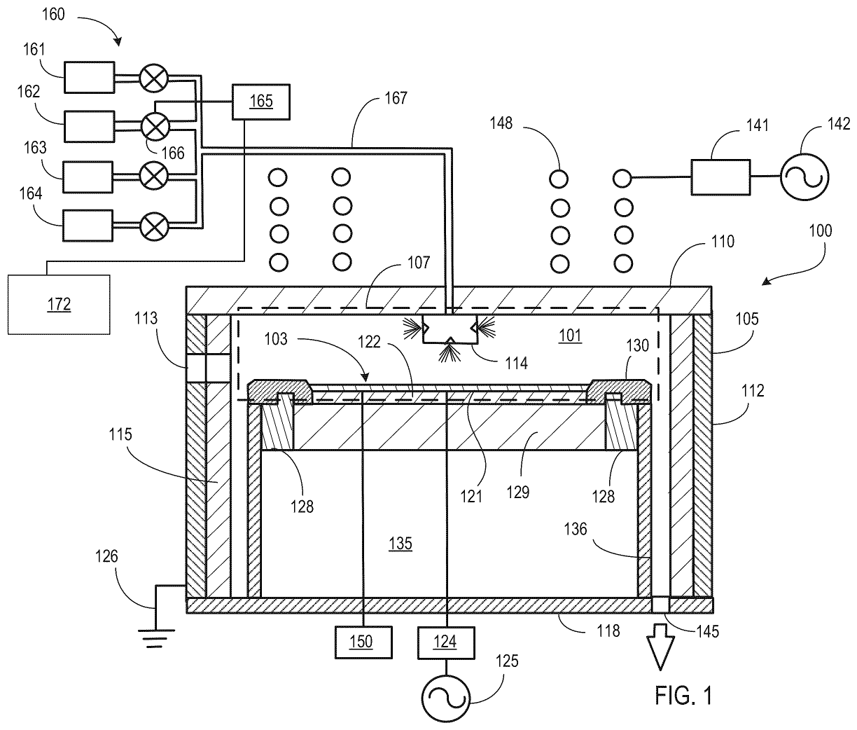

FIG. 1 illustrates a schematic cross-sectional view of an example processing chamber 100 suitable for etching one or more material layer(s) disposed on a substrate 103 (e.g., also referred to as a “wafer”) in the processing chamber 100, e.g., a plasma processing chamber. The processing chamber 100 includes a chamber body 105 defining a chamber volume 101 in which a substrate can be processed. The chamber body 105 has sidewalls 112 and a bottom 118 which are coupled with ground 126. The sidewalls 112 can include a liner 115 to protect the sidewalls 112 and extend the time between maintenance cycles of the plasma processing chamber 100. The chamber body 105 is supportive of a chamber lid assembly 110 to enclose the chamber volume 101. The chamber body 105 can be fabricated from, for example, aluminum or other suitable materials. A substrate access port 113 is formed through the sidewall 112 of the chamber body 105, which can facilitate the transfer of the substrate 103 into and out of the plasma processing chamber 100. Access port 113 can be coupled with a transfer chamber and/or other chambers (not shown) of a substrate processing system, e.g., to perform other processes on the substrate. A pumping port 145 is formed through the bottom 118 of the chamber body 105 and connected to the chamber volume 101. A pumping device can be coupled through the pumping port 145 to the chamber volume 101 to evacuate and control the pressure within the processing volume. The pumping device can include one or more pumps and throttle valves.

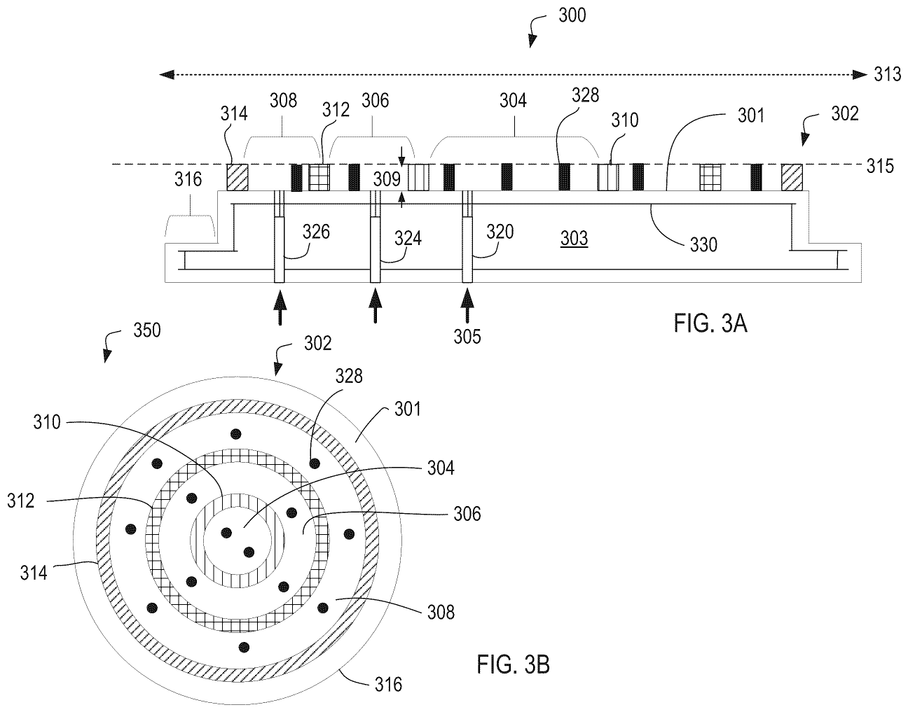

Chamber volume 101 includes a processing region 107, e.g., a station for processing a substrate. A substrate support 135 can be disposed in the processing region 107 of chamber volume 101 to support the substrate 103 during processing. The substrate support 135 can include an electrostatic chuck 122 for holding the substrate 103 during processing. The electrostatic chuck (“ESC”) 122 can use the electrostatic attraction to hold the substrate 103 to the substrate support 135. The ESC 122 can be powered by an RF power supply 125 integrated with a match circuit 124. The ESC 122 can include an electrode 121 embedded within a dielectric body. The electrode 121 can be coupled with the RF power supply 125 and can provide a bias which attracts plasma ions, formed from the process gases in the chamber volume 101, to the ESC 122 and substrate 103 seated on the pedestal. The RF power supply 125 can cycle on and off, or pulse, during processing of the substrate 103. The ESC 122 can have an isolator 128 for the purpose of making the sidewall of the ESC 122 less attractive to the plasma to prolong the maintenance life cycle of the ESC 122. Additionally, the substrate support 135 can have a cathode liner 136 to protect the sidewalls of the substrate support 135 from the plasma gases and to extend the time between maintenance of the plasma processing chamber 100. Further details related to the ESC are discussed with reference to FIGS. 3A, 3B, 4A, 4B, and 5.

Electrode 121 can be coupled with a DC power source 150. The power source 150 can provide a chucking voltage of about 200 volts to about 2000 volts to the electrode 121, e.g., provide a retaining force. The power source 150 can also include a system controller for controlling the operation of the electrode 121 by directing a DC current to the electrode 121 for chucking and de-chucking the substrate 103. The ESC 122 can include heaters disposed within the ESC 122 and connected to a power source for heating the substrate, while a cooling base 129 supporting the ESC 122 can include conduits for circulating a heat transfer fluid to maintain a temperature of the ESC 122 and substrate 103 disposed thereon. The ESC 122 can be configured to perform in the temperature range required by the thermal budget of the device being fabricated on the substrate 103. For example, the ESC 122 can be configured to maintain the substrate 103 at a temperature of about −150° C. or lower to about 500° C. or higher depending on the process being performed. A cover ring 130 can be disposed on the ESC 122 and along the periphery of the substrate support 135. The cover ring 130 can be configured to confine etching gases to a desired portion of the exposed top surface of the substrate 103, while shielding the top surface of the substrate support 135 from the plasma environment inside the plasma processing chamber 100.

A gas panel 160 (e.g., also referred to herein as “gas distribution manifold”) can be coupled by a gas line 167 with the chamber body 105 through chamber lid assembly 110 to supply process gases into the chamber volume 101. The gas panel 160 can include one or more process gas sources 161, 162, 163, 164 and can additionally include inert gases, non-reactive gases, and reactive gases, as can be used for any number of suitable processes. Examples of process gases that can be provided by the gas panel 160 include, but are not limited to, hydrocarbon containing gases including methane, sulfur hexafluoride, silicon chloride, silicon tetrachloride, carbon tetrafluoride, hydrogen bromide. Process gases that can be provided by the gas panel can include, but are limited to, argon gas, chlorine gas, nitrogen, helium, or oxygen gas, sulfur dioxide, as well as any number of additional materials. Additionally, process gasses can include nitrogen, chlorine, fluorine, oxygen, or hydrogen containing gases including, for example, BCl₃, C₂F₄, C₄F₈, C₄F₆, CHF₃, CH₂F₂, CH₃F, NF₃, NH₃, CO₂, SO₂, CO, N₂, NO₂, N₂O, and H₂, among any number of additional suitable precursors. Process gases from process gas sources, e.g., sources 161, 162, 163, 164, can be combined to form one or more etching gas mixtures. For example, gas panel 160 includes one or more process gas sources specific to oxide-based etching chemistries. In another example, gas panel 160 includes one or more process gas sources specific to nitride-based etching chemistries.

Gas panel 160 includes various valves, pressure regulators (not shown), and mass flow controllers (not shown) arranged with respect to the gas sources 161, 162, 163, 164 to control the flow of the process gases from the sources. Valves 166 can control the flow of the process gases from the sources 161, 162, 163, 164 from the gas panel 160. Operations of the valves, pressure regulators, and/or mass flow controllers can be controlled by a controller 165. Controller 165 can be operably coupled to an electro-valve (EV) manifold (not shown) to control actuation of one or more of the valves, pressure regulators, and/or mass flow controllers. The lid assembly 110 can include a gas delivery nozzle 114. The gas delivery nozzle 114 can include one or more openings for introducing the process gases from the sources 161, 162, 163, 164 of the gas panel 160 into the chamber volume 101. After the process gases are introduced into the plasma processing chamber 100, the gases can be energized to form a plasma. An antenna 148, such as one or more inductor coils, can be provided adjacent to the plasma processing chamber 100. An antenna power supply 142 can power the antenna 148 through a match circuit 141 to inductively couple energy, such as RF energy, to the process gas to maintain a plasma formed from the process gas in the chamber volume 101 of the plasma processing chamber 100. Alternatively, or in addition to the antenna power supply 142, process electrodes below the substrate 103 and/or above the substrate 103 can be used to capacitively or inductively couple RF power to the process gases to maintain the plasma within the chamber volume 101. The operation of the power supply 142 can be controlled by a controller, such as controller 165, that also controls the operation of other components in the plasma processing chamber 100.

The controller 165 can be used to control the process sequence, regulating the gas flows from the gas panel 160 into the plasma processing chamber 100, and other process parameters. Software routines, when executed by a computing device having one or more processors (e.g., a central processing unit (CPU)) in data communication with one or more memory storage devices, transform the computing device into a specific purpose computer such as a controller, which can control the plasma processing chamber 100 such that the processes are performed in accordance with the present disclosure. The software routines can also be stored and/or executed by one or more other controller(s) that can be associated with the plasma processing chamber 100.

In some embodiments, controller 165 is in data communication with a characterization device 172. Characterization device 172 can include one or more sensors (e.g., image sensors) operable to collect processing data related to processing chamber 100. For example, characterization device 172 includes an optical emission spectroscopy device configured to monitor a signal, e.g., emitted light of a plasma, within a processing region of the processing chamber 100. For example, a signal can be a primary or highest intensity wavelength of emitted light. Characteristics of the emitted light (e.g., wavelength and intensity) from the plasma within the processing region can depend in part on an etching gas mixture used to generate the plasma as well as a layer composition of the layer being etched. For example, each etching gas mixture and corresponding layer composition being etched can have a respective signal signature. Emitted wavelengths that are unique or distinguishing for each etching gas mixture and corresponding layer composition can be monitored to determine an etching condition of the layer being etched. For example, a thickness remaining of the layer being etched. Characteristics of the emitted light from the plasma can change, e.g., based on the etching process. For example, an intensity of a monitored signal can change as material is removed from the layer being processed. Characterization device 172 can be configured to collect processing data including the respective signals corresponding to the etching gas mixtures utilized in the wafer processing and corresponding layer compositions of the structure being processed in the processing chamber 100. Controller 165 can receive processing data from the characterization device 172 and determine, from the processing data, one or more actions to perform.

In some embodiments, at a termination point of etching process(es) for the wafer, an automatic or semi-automatic robotic manipulator (not shown) can be utilized to transfer the wafer(s) from the substrate support out of the process chamber, e.g., through substrate access port 113. For example, the robotic manipulator can transfer the wafer to another chamber (or another location) to perform another step in a fabrication process.

In some embodiments, portions of the substrate support 135, for example, the electrostatic chuck 122, can be adapted to compensate for non-uniformities in etch rates across a substrate retained by the substrate support 135. Non-uniformities in the etch rates can arise due to non-uniformities in temperature across the substrate, e.g., due to different plasma loading in the fabrication tool. Non-uniformities in the etch rates across the substrate can be process dependent, for example, can differ between dielectric-etch processes and conductor-etch processes. Non-uniformities in etch rates across the substrate can be fabrication tool dependent, e.g., can differ between fabrication tools due to tolerances, age, calibration, etc., of each fabrication tool. Generating an ESC design to compensate for a particular non-uniformity for a fabrication tool, process, etc., can result in higher fidelity from a fabrication process on a substrate, e.g., higher yield of fabricated components.

In some embodiments, designing an ESC to improve process uniformity across a substrate includes adapting various design parameters for the ESC. Relationships between the various design parameters in an ESC design can be complex, where a design parameter may affect one or more other design parameters. Adapting the various design parameters into an ESC design can yield a unique solution for an ESC to improve process uniformity (e.g., temperature uniformity) across a substrate during a fabrication process.

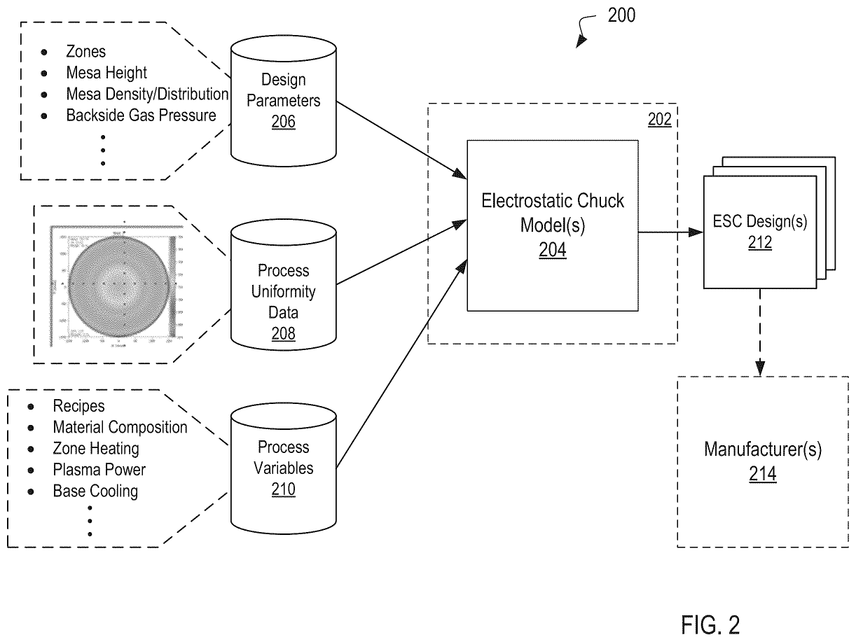

FIG. 2 shows an example operating environment 200 for an electrostatic chuck (ESC) design system 202. ESC design system 202 includes ESC model(s) 204. ESC model 204 can include, for example, a machine learning model, where the machine learning model can be trained using supervised or unsupervised learning. The ESC design system 202 can use one or more ESC model(s) 204 to generate simulations of the process behavior for an ESC design to model an impact of a set of variables on an outcome of the performance of the ESC design. For example, the one or more model(s) 204 can be used to generate simulations of the cooling behavior (e.g., temperature uniformity) of an ESC design based on a set of variables, e.g., design parameters and/or process variables. The ESC model 204 can be configured to receive (i) design parameters 206, (ii) process uniformity data 208, (iii) process variables 210, or (iv) any combination thereof, as input. The ESC model 204 can generate predictions, e.g., ESC designs 212, as output. The generated predictions from ESC model 204 can be ESC designs that are likely (e.g., have an increased likelihood) of improved performance, temperature uniformity, ease of manufacturing, or the like. For example, the ESC model 204 can generate ESC design predictions that are optimized for a thermal management across a surface of the substrate during the fabrication process.

Design parameters 206 include features or components of the ESC that can be configurable (e.g., adjustable) in response to a process non-uniformity, e.g., temperature non-uniformity of a substrate retained by the ESC, during a fabrication process. Design parameters 206 can include material compositions of one or more of the components of the ESC, for example, a material composition of the body of the ESC. At times, the body of the ESC is composed of a ceramic material, e.g., Al₂O₃ and/or AlN.

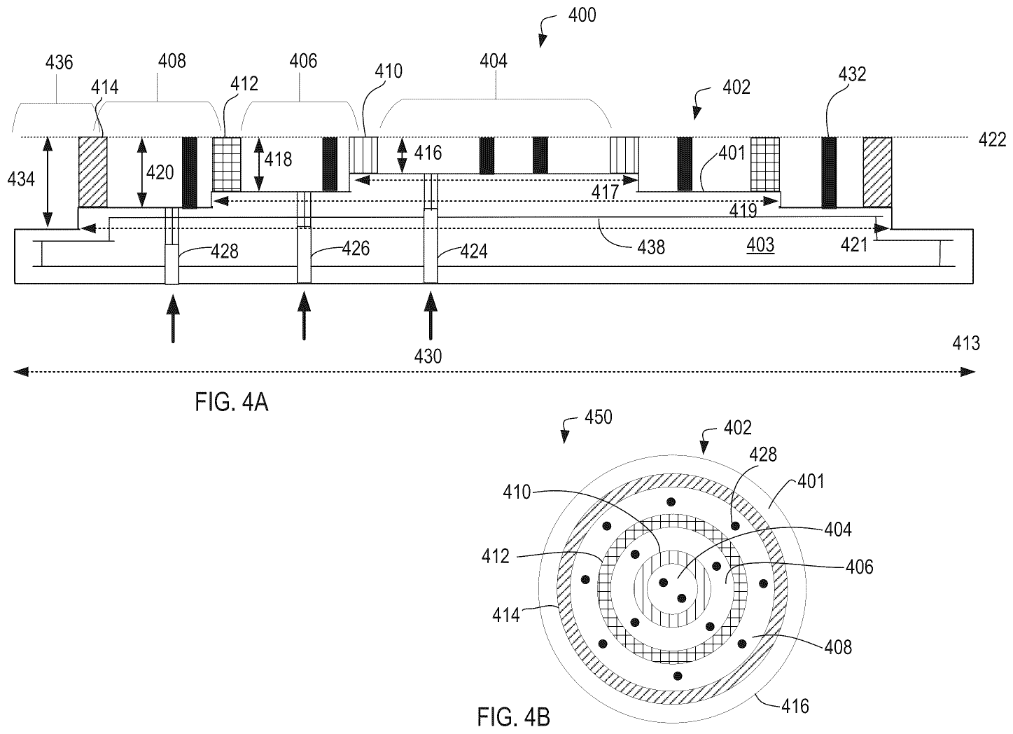

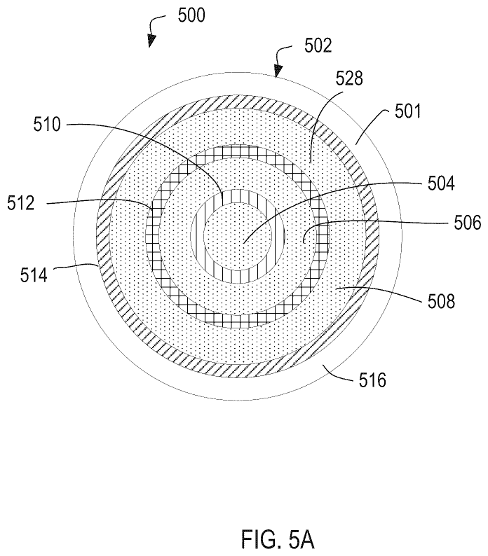

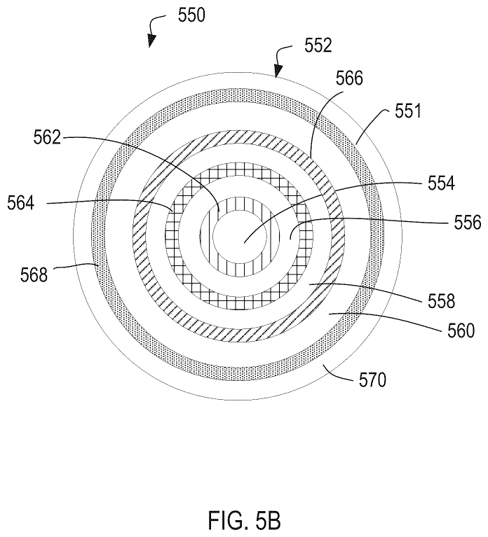

Design parameters 206 can include a number of cooling regions on a surface of the ESC, e.g., on a surface of the ceramic body of the ESC, e.g., as described in further detail with reference to FIGS. 3A and 3B, and FIG. 5B. For example, a number of cooling regions can be three or more (e.g., three, four, five, six, seven, or more) cooling regions. Design parameters 206 can include a distance between the surface of the ceramic body of the ESC and a backside of the substrate when the substrate is retained (e.g., held, chucked, affixed, etc.) by the ESC, e.g., as described in further detail with reference to FIGS. 4A and 4B. For example, a distance between the surface of the ceramic body of the ESC and the backside of the substrate in a cooling region can adjust a heat transfer coefficient in the cooling region. Design parameters 206 can include distribution and density of supportive structures, e.g., mesas, arranged on the surface of the ceramic body of the ESC and within each of the number of cooling regions on the surface of the ESC, e.g., as described in further detail with reference to FIG. 5A. For example, different densities of the mesas can result in contact-dominated or gas-dominated cooling.

Process uniformity data 208 can include direct and/or indirect measurements of process uniformity for a fabrication process on a fabrication tool. Process uniformity data 208 can be generate for fabrication processes including corresponding process variables 210. Process uniformity data can include, for example, etch rate data corresponding to etch rates across a substrate for a fabrication process using a set of process variables 210. The etch rate data can be generated using metrology tools, e.g., ellipsometry, interferometry, etc., to characterize an etch performed on a substrate. Etch rate data can include an etch rate map of the substrate including multiple sample points, where an etch rate at each of the multiple sample points is determined. Process uniformity data can include, for example, temperature data for one or more points along a substrate during a fabrication process. Temperature data can be generated using, for example, an optical probe to measure a non-contact backside substrate temperature. In another example, temperature data can be generated using interferometry (e.g., etalon interferometry) to measure a center point temperature of a surface of the substrate.

Process variables 210 include, for example, etch material composition and a recipe used to perform a fabrication process, e.g., an etching process. The recipe can include instructions to control operations of a fabrication tool, for example, to control plasma power, substrate temperature, etch times, and the like, during the fabrication process using the recipe.

The recipe can also include instructions for temperature control for one or more temperature regulatory components of the ESC. In particular, a recipe can include instructions for controlling operation of one or more electrodes within the ceramic body for generating localized heating. The one or more electrodes can include, for example, multiple zone heaters, where each of the multiple zone heaters is operable to heating a portion of the ESC. For example, the multiple zone heaters can include two, three, or four zone heaters. In another example, the multiple zone heaters can be micro-zone (e.g., pixel) heaters, where the ESC can include about 20, 40, 50 100, 150, 200, or more micro-zone heaters each operable to heat a portion of the ESC. The recipe can include instructions for controlling operation of cooling channels (e.g., flow of a coolant, temperature of the coolant, etc.) located in a cooling base of the substrate support (e.g., cooling base 139 of substrate support 135). In some implementations, the recipe includes instructions for controlling operation of gas flow through multiple conduits within the ceramic body of the ESC and to the cooling regions of the surface of the ESC, e.g., as described in further detail with reference to FIGS. 3A and 3B.

An output of ESC model 204 can include an ESC design 212 specifying implementations of the one or more of the features/components of the design parameters 206. For example, the ESC design 212 can include a number of cooling regions, a density/distribution of supportive structures within each of the number of cooling regions, and dimensions of the supportive structures within each of the number of cooling regions. In some embodiments, the ESC design 212 can include operation parameters, for example, gas pressure(s) to provide to each of the number of cooling regions during a fabrication process.

In some embodiments, the generated ESC designs 212 can be provided to manufacturer(s) 214 to fabricate the ESC based on the ESC design(s) 212. At times, ESC fabrication can be performed using one or more manufacturing techniques, for example, using wet casting, subtractive manufacturing, additive manufacturing, sintering, diffusion bonding, etc.

FIGS. 3A and 3B shows various schematic views of example portions of an electrostatic chuck. FIG. 3B depicts a schematic plan-view 350 of a top surface of a ceramic body an example electrostatic chuck 302, where the top surface 301 having a diameter 313 faces a backside of a substrate when the substrate is retained by the ESC 302. As referred to in this specification, the backside of the substrate is a surface opposing a processing surface, e.g., a surface undergoing an etch process within a fabrication tool. At times, the backside of the substrate is a surface opposing a surface where one or more films are formed on a wafer/carrier structure of the substrate.

The ESC 302 can include one or more cooling regions defined between the backside of the substrate and the top surface of the ESC. The one or more cooling regions each have an outer edge defined by a respective retaining ring formed on the top surface of the ESC. The retaining ring(s) can be formed on the top surface of a same ceramic material composition as the ceramic body of the ESC. For example, the retaining ring(s) can be formed using subtractive manufacturing of a ceramic body and/or additive manufacturing such that the retaining ring(s) and ceramic body are a monolithic structure. A gas (e.g., helium) can be introduced into the cooling region(s) through the body of the ESC and into the cooling region(s) to provide cooling to a portion of the substrate corresponding to the cooling regions. As depicted, ESC 302 includes three cooling regions 304, 306, and 308, arranged on a top surface of a ceramic body of the ESC, where each cooling region has an outer edge defined by a respective retaining ring 310, 312, and 314. Although discussed with reference to FIGS. 3A and 3B as including three cooling regions, more or fewer cooling regions are possible. For example, four, five, six, seven, or more cooling regions each defined at an outer edge by a respective retaining ring. A positive pressure of gas can be introduced into each of the multiple cooling regions, where a flow of the introduced gas can be separately (e.g., independently) controlled. Independent control of the flow of gas to each of the multiple cooling regions can include control of gas flow using of flow meters and valves, to provide a same or different gas flow to each of the multiple cooling regions. In some embodiments, controlling a flow of the gas to a given cooling region controls a degree of cooling applied to a portion of the substrate corresponding to the cooling region. At times, a different amount of cooling can be applied to different portions of the substrate corresponding to different cooling regions by a controller operating a flow of gas to each cooling region.

In the example ESC 302 depicted in FIGS. 3A and 3B, top surface 301 of a ceramic body 303 includes an edge region 316 located outside retaining ring 314 and not included within a cooling region 304, 306, or 308. Retaining rings 310, 312, and 314 are arranged concentrically with respect to a center point 318 of the top surface 301 of the ESC 302. Although depicted in FIGS. 3A and 3B as evenly spaced, the retaining rings can be unevenly spaced apart. A height 309 of each retaining ring 310, 312, 314 is substantially equal, such that when a substrate is retained by the ESC 302, an airtight seal is formed in each cooling region 304, 306, 308. In other embodiments, an ESC may not include an edge region.

An inner cooling region 304 defined by retaining ring 310 encloses a circular volume. Specifically, when a substrate is retained by the ESC 302, a volume is defined by the inner surface of the retaining ring 310, the top surface 301 of the ESC 302, and a backside of the substrate aligned on a plane 315, e.g., as depicted in FIG. 3A in a partial cross-sectional view 300 of an ESC.

Cooling regions are coupled to one or more gas conduits, e.g., gas conduits 320, 322, 324, within the ceramic body 303 of the ESC 302 and configured to introduce gas, e.g., gas flow 305, into each of the cooling regions. The gas conduits can fluidically couple a gas source (e.g., from a sub-assembly of the ESC) through a portion of the ceramic body 303 and to top surface 301 of the ESC 302. Gas conduits, e.g., gas conduit 320, 322, and 324, can each include a porous plug. A porous plug can be composed of a different material composition and/or have different internal structure (e.g., porosity) than the ceramic body of the ESC. The porous plug can be configured to allow a flow of gas through the porous plug to the top surface of the ceramic body and restrict (e.g., prevent) contaminants from the top surface of the ceramic body from backflowing into the gas conduit. The gas conduits can include gas exit holes, e.g., laser-drilled or AM-defined holes, located in the gas flow path between the porous plug and the top surface of the ceramic body. The gas exit holes can be arranged in an array of exit holes with respect to the porous plug. The gas exit holes can be configured to allow a flow of gas through the gas exit holes and to the surface of the ceramic body, but restrict (e.g., prevent) contaminants from the top surface of the ceramic body from backflowing into the gas conduit.

Though depicted in FIG. 3A as a respective gas conduit in each cooling region, a cooling region may have two or more gas conduits introducing gas into the cooling region. The gas conduits can introduce helium, argon, nitrogen, or another inert gas into each of the cooling regions. The gas pressure within the cooling regions can operate in a conductance zone, for example, low to negligible turbulence introduced into the cooling region by the gas when operating in a steady-state condition. A gas pressure for a cooling region can be selected based in part on a thermal conductivity requirement for the cooling region. For example, a higher gas pressure introduced into a cooling region can generate a larger thermal conductivity than a lower gas pressure, for a given gas.

The volumes defined in each of the cooling regions are substantially gas-tight and can hold positive pressure for a duration of time. Positive pressure can include between about 1 Torr and about 50 Torr. For example, positive pressure can include at least about 2 Torr, 5 Torr, 10 Torr, 15 Torr, 20 Torr, 25 Torr, or more. A positive pressure can be based on an amount of chucking force exerted on the backside of the substrate by electrode 121. For example, the positive pressure can be selected to exert less force on the backside of the substrate than a chucking force exerted between the electrode and the backside of the wafer during a fabrication process.

In some embodiments, cooling regions 304, 306, and 308 include one or more supportive structures, e.g., supportive structure 328. The supportive structures, e.g., mesas, are arranged on the top surface 301 of the ceramic body 303 and extending to plane 315, e.g., a height 309. The height 309 of the supportive structures can be (e.g., substantially) of equal height and additionally (e.g., substantially) equal to height of the retaining rings 310, 312, and 314 such that the supportive structures each contact a backside surface of the substrate when the substrate is retained by the ESC.

Although depicted in FIGS. 3A and 3B as a sparse distribution of supportive structures, the supportive structures may be evenly or unevenly distributed within the cooling regions 304, 306, and 308 and with respect to the retaining rings 310, 312, and 314, as discussed in further detail with respect to FIG. 5A. In some embodiments, supportive structures 328 include a cylindrical shape, with a circular cross-section parallel to the top surface of the ceramic body of the ESC, e.g., as depicted in FIG. 3B. Other cross-sectional shapes may be possible, for example, rectangular, polygonal, and the like. In some embodiments, a combination of two or more different types of shapes can be used, e.g., each cooling region having a respective type of shape, or a mix of two or more types of shapes in a cooling region. A minimum density of supportive structures in a cooling region can be set based on a number of supportive structures required to maintain at least a threshold flatness of a substrate when the substrate is retained by the ESC. For example, a minimum density of supportive structures in a cooling region can be set to prevent bowing or flexing of the substrate when the substrate is chucked/de-chucked, e.g., by electrode 121.

In some embodiments, different pressures of gas can be introduced into the cooling regions through gas conduits 320, 324, 326, e.g., by a controller operating respective flow regulators, valves, etc. The different pressures of gas can be used to counteract non-uniform heating of the substrate, e.g., by the plasma, during the fabrication process. For example, at times, a center region and/or edge region of the substrate may be hotter than a middle region of the substrate during the fabrication process.

During operation of a fabrication tool including the ESC, a recipe for a fabrication process can include a higher pressure into an inner region 304 and a lower pressure into an outer region 308. For example, an inner region 304 gas pressure can be 20 Torr, while an outer cooling region 308 gas pressure can be 10 Torr, and where a middle cooling region 306 can be pressurized at 15 Torr.

In some embodiments, a same pressure of gas can be introduced by respective gas conduits into the cooling regions during a fabrication process. In some embodiments, a pressure of gas introduced by the respective gas conduits into one or more of the cooling regions can be dynamically adjusted during a fabrication process, e.g., included recipe instructions for the fabrication process. The dynamic pressure adjustments in the cooling regions can be used to adjust a process temperature of the substrate retained by the ESC 302, which in turn can adjust an etch rate in respective cooling regions.

For simplicity and to highlight the features discussed above, FIGS. 3A and 3B depict portions of the ESC 302 where some components, notably embedded electrodes within the ceramic body of the ESC (e.g., multiple heating elements and/or microzone heaters), are not depicted. An embedded electrode 330 within the ceramic body of the ESC, e.g., electrode 121 depicted in FIG. 1, for providing a retaining force on a substrate (e.g., chucking force) when the substrate is retained/chucked to the ESC is depicted in FIG. 3A.

Design parameters 206 can include a distance between the surface of the ceramic body of the ESC and a backside of the substrate when the substrate is retained (e.g., held, chucked, affixed, etc.) by the ESC. For example, a distance between the surface of the ceramic body of the ESC and the backside of the substrate in a cooling region can adjust a heat transfer coefficient in the cooling region.

FIGS. 4A and 4B shows various schematic views and of portions of an example electrostatic chuck. As depicted in cross-sectional view 400 in FIG. 4A and plan-view 450 in FIG. 4B, a ceramic body 403 can have a top surface 401 having a diameter 413 and including multiple tiers with respective diameters 417, 419, 421, where each tier defines a cooling region. For example, cooling regions 404, 406, and 408 where each cooling region has a respective retaining ring 410, 412, and 414 defining an outer edge of the cooling region. Each of the cooling regions 404, 406, and 408 have a respective distance 416, 418, and 420 from the top surface 401 of the ESC 402 to a plane 422 that is co-planar with a backside of a substrate when the substrate is retained by the ESC 402. Accordingly, retaining rings 410, 412, and 414 have corresponding heights with the distances 416, 418, and 420 for the cooling regions 404, 406, and 408, respectively.

Cooling regions include one or more gas conduits, e.g., gas conduits 424, 426, and 428, within the ceramic body of the ESC and configured to introduce gas, e.g., gas flow 430, into each of the cooling regions. Though depicted in FIG. 4A as a respective gas conduit in each cooling region, a cooling region may have two or more gas conduits introducing gas into the cooling region. For example, the gas conduits can introduce helium or another gas into each of the cooling regions.

In some embodiments, cooling regions 404, 406, and 408 include one or more supportive structures, e.g., supportive structure 432. The supportive structures, e.g., mesas, arranged on the top surface of the ceramic body. The supportive structures can be (e.g., substantially) of equal height to distances 416, 418, 420 of the corresponding regions and additionally (e.g., substantially) equal to heights of the retaining rings 410, 412, and 414 such that respective surfaces of the supportive structures each contact a backside surface of the substrate when the substrate is retained by the ESC, e.g., on plane 422. In one example, distances 416, 418, and 420 can be related by X, 2X, and 4X in magnitude, respectively, where distance 416 is a distance X, distance 418 is a distance 2X, and distance 420 is a distance 4X from the top surface 401 to the plane 422.

Although depicted in FIGS. 4A and 4B as a sparse distribution of supportive structures, the supportive structures may be evenly or unevenly distributed within the cooling regions 404, 406, and 408 and with respect to the retaining rings 410, 412, and 414, as discussed in further detail with respect to FIG. 5A.

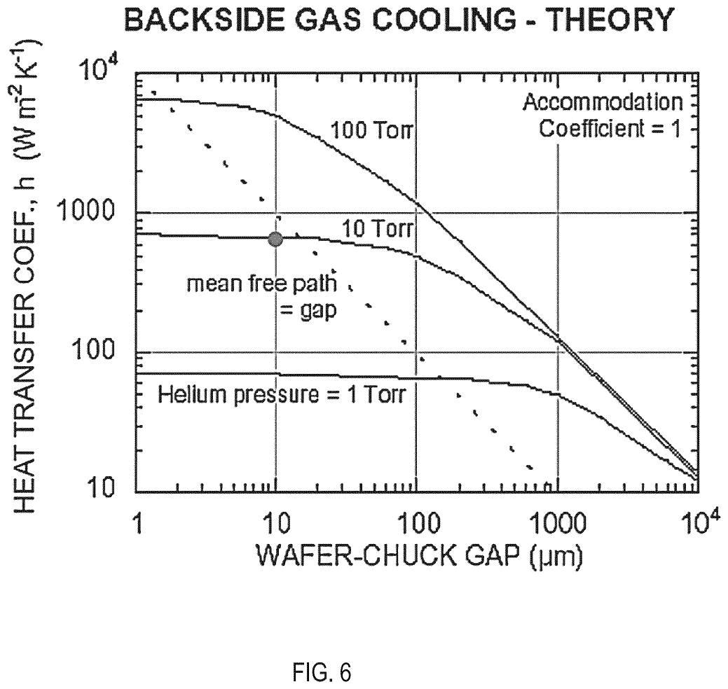

Distances 416, 418, and 420 of the cooling regions 404, 406, and 408 between the top surface 401 of the ESC 402 and the plane 422 can be selected based in part to counteract localized heating of a substrate retained by the ESC during a fabrication process. For example, a shallower distance between top surface 401 and plane 422 has a larger heat transfer coefficient than a larger distance between top surface 401 and plane 422, e.g., as depicted in FIG. 6. A relationship between a heat transfer coefficient and a gap between a backside of the substrate and top surface of the ESC (e.g., also referred to as “wafer-chuck gap”) is depicted in FIG. 6 in terms of different gas pressures introduced into the volume defined by the cooling region and including the gap. Briefly, for a given wafer-chuck gap, as a positive pressure within cooling region increases, a heat transfer coefficient also increases, resulting in more efficient heat removal from the area. Moreover, for a given positive pressure introduced into a cooling region, a smaller wafer-chuck gap will have a larger heat transfer coefficient (and resulting increased efficiency of heat removal) than a larger wafer-chuck gap. At times, an interplay between a wafer-chuck gap for a cooling region and a positive pressure of gas flow can be selected for a cooling region to achieve a threshold heat transfer coefficient and resulting heat removal efficiency.

As depicted in cross-sectional view 400, an edge region can be at a distance 434 from plane 422, where the edge region 436 may or may not include supportive structures. In some embodiments, distance 434 from top surface 401 to plane 422 in the edge region 436 is larger than each distance 416, 418, and 420.

In some embodiments, to counteract non-uniform heating of a substrate retained by the ESC during a fabrication process, different distances between the top surface 401 and the plane 422 can be selected for the ESC.

An electrode 438, e.g., electrode 121 depicted in FIG. 1, for providing a retaining force on a substrate (e.g., chucking force) when the substrate is retained/chucked to the ESC is depicted in FIG. 4A. For simplicity and to highlight the features discussed above, FIG. 4A depicts a portion of the ESC 402, where some components, notably the heater electrodes (e.g., multiple heating elements and/or microzone heaters) are not depicted.

In some embodiments, design parameters can include a distribution and density of supportive structures, e.g., mesas, arranged on the surface of the ceramic body of the ESC and within each of the number of cooling regions on the surface of the ESC. For example, different densities of the mesas can result in contact-dominated or gas-dominated cooling.

FIG. 5A shows a plan view 500 of a portion of an example electrostatic chuck. Plan-view 500 of an example top surface 501 of an ESC 502 includes multiple cooling regions 504, 506, and 508. Cooling regions 504, 506, and 508 are defined at an outer edge by respective retaining rings 510, 512, and 514. In some embodiments, as depicted in FIG. 5A, an edge region 516 is defined by an outer edge of retaining ring 514, where the edge region 516 is not included in a cooling region.

Cooling regions 504, 506, and 508 include supportive structures, e.g., supportive structure 528. Supportive structures, e.g., mesas, are arranged on the top surface of the ceramic body and extend to a (e.g., substantially) equal height and additionally (e.g., substantially) equal to height of the retaining rings 510, 512, and 514 such that the supportive structures each contact a backside surface of the substrate when the substrate is retained by the ESC, e.g., as discussed with reference to FIGS. 3A and 3B.

In some embodiments, one or more of the cooling regions can include different densities of supportive structures. A density of supportive structures in a cooling region can be a below a threshold density such that the cooling of the cooling region is gas-dominated in that region. In other words, the dominant contributor to cooling in the cooling region is due to the positive gas pressure, e.g., helium pressure, introduced by gas conduits into the cooling region when a substrate is retained by the ESC. In a gas-dominated cooling regime, the contact points between the supportive structures and retaining rings and the backside of the substrate when the substrate is retained by the ESC is a secondary cooling mechanism for the cooling region.

In some embodiments, a density of supportive structures in a cooling region can be above a threshold density such that the cooling of the cooling region is contact-dominated in that region. In other words, the dominant contributor to cooling in the region is localized to the points of contact between the supportive structures and the retaining rings, and the backside of the substrate when the substrate is retained by the ESC. In a contact-dominated cooling regime, the gas cooling mechanism is a secondary cooling mechanism for that cooling region.

Though depicted in FIG. 5A as equal densities of supportive structures in each of the cooling regions, in some embodiments, a density of supportive structures can vary from a center cooling region to an outer cooling region of the ESC. For example, a center cooling region, e.g., cooling region 504, can have a 0.75x density of supportive structures, a middle cooling region, e.g., cooling region 506, can have a 1x density of supportive structures, and an outer region, e.g., cooling region 508, can have a 1.25x density of supportive structures. In another example, two of the cooling regions can have a same density of supportive structures.

In some embodiments, one or more of the cooling regions can include a non-uniform distribution of the supportive structures. For example, a cooling region can include a gradient of a density of the supportive structures arranged with respect to the top surface 501 of the ceramic body of the ESC. A higher density of supportive structures can be located adjacent to one or more retaining rings bounding the cooling region and graduate to a lower density of supportive structures in a central region of the cooling region. Gradients of density of the supportive structures can reduce a sharpness of a boundary between contact-dominated cooling at the retaining ring to the gas-dominated cooling in a central region of the cooling zone.

In some embodiments, a number of cooling regions included in an ESC design includes four or more cooling regions arranged on a top surface 551 of an ESC 552. For example, as depicted plan-view 550 of ESC 552 in FIG. 5B, an ESC 552 includes four cooling regions, e.g., 554, 556, 558, and 560. Cooling regions 554, 556, 558, and 560 are defined at an outer edge by respective retaining rings 562, 564, 566, and 568. In some embodiments, as depicted in FIG. 5D, an edge region 570 is defined by an outer edge of retaining ring 568, where the edge region 570 is not included in a cooling region.

In some embodiments, one or more of the features described with reference to FIGS. 3, 4, and 5 can be considered for incorporation into an ESC design. In some embodiments, all the features described with reference to FIGS. 3, 4, and 5 can be considered for incorporation into an ESC design.

As described in this specification, introducing gas into the cooling regions of the ESC can generate a primary temperature control for the substrate during a fabrication process. In some embodiments, as described with reference to FIG. 1, the ESC includes one or more heaters. At times, the ESC can include multiple heating zones (e.g., by multiple heating elements) that can generate a secondary temperature adjustment during the fabrication process, where the heating zones can locally (and independently) adjust temperature of the substrate in the heating zones during the fabrication process. The multiple heating zones (e.g., four heating zones) can be located within the ceramic body and further spaced apart from the top surface of the ceramic body of the ESC. As such, the respective effects by the multiple heating zones can be (at times) less than the effects of the gas-pressurized cooling zones as described above.

In some embodiments, the ESC can include (e.g., further include) microzone heaters that can generate a tertiary temperature adjustment during the fabrication process, where the microzone heaters can locally (and independently) adjust temperature of the substrate in the “pixel-like” zones of the microzone heaters during the fabrication process. The microzone heaters can be located within the ceramic body and further spaced apart from the top surface of the ceramic body of the ESC from the multiple heater zones. As such, the respective effects by the microzone heaters can be (at times) less than the effects of the multiple heating zones and the gas-pressurized cooling zones as described above.

In some embodiments, a controller (e.g., controller 165) of a fabrication tool can execute a recipe including instructions for a fabrication process. The recipe can include temperature-control instructions executable by the controller 165 to control operations of various temperature-related components of the fabrication tool. For example, the temperature-related components can include (A) gas pressures introduced into each of the cooling regions of the ESC, (B) temperature settings for each of the multiple heaters with respective heating zones within the ceramic body of the ESC, (C) temperature settings for each of the microzone heaters within the ceramic body of the ESC, (D) coolant flow into cooling channels located in a base of the substrate support, or (E) any combination thereof. The recipe instructions can additionally include executable instructions related to other process parameters in addition to the operations of the ESC to operate components of the fabrication tool to control, for example, plasma power, flow of the etch gas, etc.

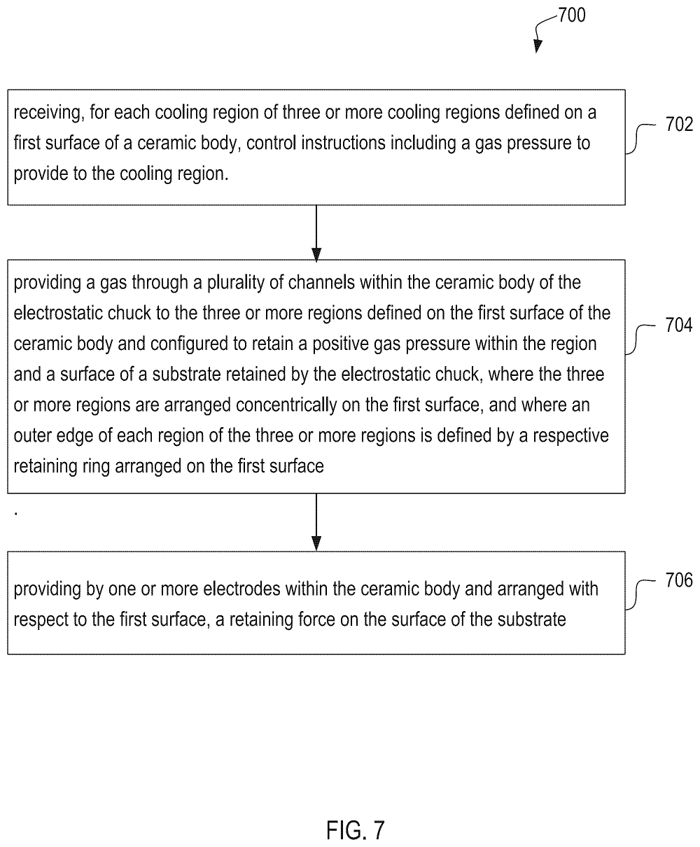

FIG. 7 shows a flow diagram of an example process for performing substrate processing. For convenience, the process 700 will be described as being performed by a system of one or more computing devices, located in one or more locations, and programmed appropriately in accordance with this specification. For example, a controller, e.g., the controller 172 of FIG. 1, appropriately programmed, can perform the process 700.

The system receives, for each cooling region of three or more cooling regions defined on a first surface of a ceramic body, control instructions including a gas pressure to provide to the cooling region (702). In some embodiments, receiving control instructions the gas pressure to provide to each cooling region of the three or more cooling regions includes receiving control instructions defined in a recipe for performing the substrate processing. In some embodiments, the recipe can include a target temperature (e.g., a substrate process temperature) for the portion of the substrate corresponding to the cooling region, where the system may determine, from the target temperature, a gas pressure to provide to the cooling region, e.g., using the backside substrate gas cooling plot depicted in FIG. 6.

The system controls a backside substrate temperature of the substrate by providing gas flow through multiple conduits within the ceramic body of the electrostatic chuck to the three or more regions defined on the first surface of the ceramic body to establish the determined gas pressures to the three or more cooling regions, where the three or more cooling regions are configured to retain positive gas pressures within the region and the surface of the substrate retained by the electrostatic chuck (704) The three or more regions are arranged concentrically on the first surface, and wherein an outer edge of each region of the three or more regions is defined by a respective retaining ring arranged on the first surface. The gas flows to each of the three or more regions can be independently provided to each of the three or more regions, where the gas flows are independently controllable by the system to provide selected gas pressures into each cooling region.

In some implementations, providing the gas through the multiple conduits within the ceramic body of the electrostatic chuck to three or more regions defined on the first surface of the ceramic body includes, providing a different gas pressure to each region of the three or more regions. At times, providing the gas through conduits within the ceramic body of the electrostatic chuck to three or more regions defined between the first surface of the ceramic body and the surface of the substrate retained by the electrostatic chuck includes cooling the surface of the substrate by contact-dominated cooling.

In some implementations, providing the gas through conduits within the ceramic body of the electrostatic chuck to three or more regions defined between the first surface of the ceramic body and the surface of the substrate retained by the electrostatic chuck includes cooling the surface of the substrate by gas-dominated cooling.

The system provides, by one or more electrodes within the ceramic body and arranged with respect to the first surface, a retaining force on the surface of the substrate (706).

In some implementations, process 700 can further include supporting the surface of the substrate by multiple supportive structures arranged on the first surface of the ceramic body and within at least one region of the three or more regions. At times, supporting the surface of the substrate by multiple supportive structures arranged on the first surface of the ceramic body includes, supporting the surface of the substrate by a different density of structures in at least one region of the three or more regions.

In some implementations, process 700 can further include providing, by one or more heating elements arranged within the ceramic body, heating of the surface of the substrate.

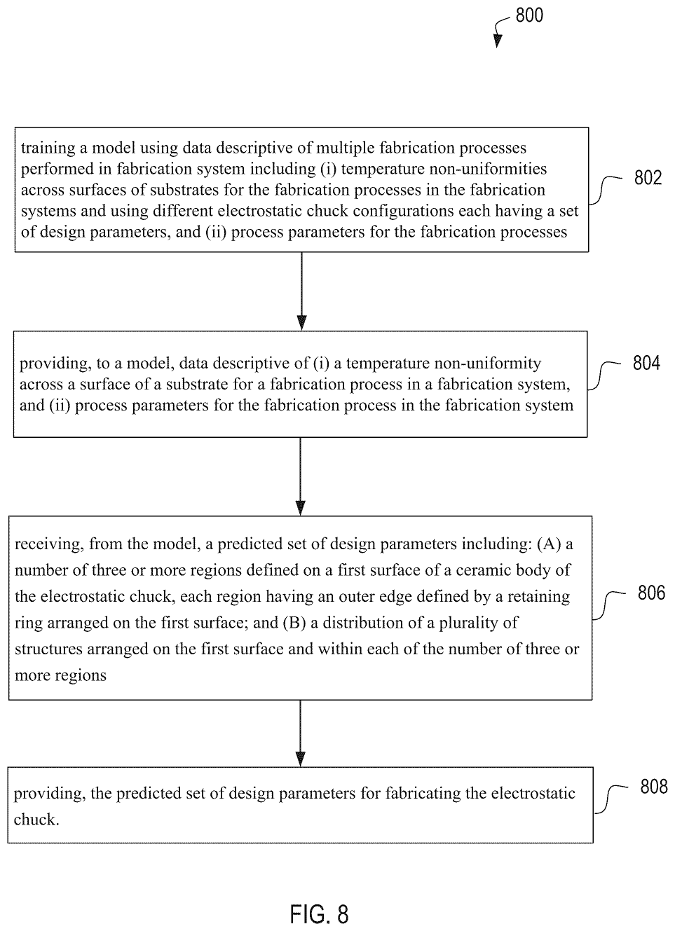

As described with reference to FIG. 2 above, a model can be used to determine a set of design parameters for an ESC to improve a temperature uniformity across a surface of a substrate for a fabrication process in a fabrication system. FIG. 8 shows a flow diagram of an example process 800 for modeling parameters of an electrostatic chuck design.

The system receives data descriptive of multiple fabrication processes performed in fabrication systems including (i) temperature non-uniformities across surfaces of substrates for the fabrication processes in the fabrication systems and using different electrostatic chuck configurations each having a set of design parameters, and (ii) process parameters for the fabrication processes in the fabrication systems and trains a model to generate parameter values used to predict design parameters of an ESC in response to a given input (802).

The system provides as input to the model, temperature non-uniformity data collected for a fabrication process performed in a fabrication system and process parameters for the fabrication process (804).

The system receives, from the model, a predicted set of design parameters including: (A) a number of three or more regions defined on a first surface of a ceramic body of the electrostatic chuck, each region having an outer edge defined by a retaining ring arranged on the first surface; and (B) a distribution of multiple supportive structures arranged on the first surface and within each of the number of three or more regions is received from the model (806).

In some implementations, the first surface of the ceramic body is aligned along a plane parallel to a surface of a substrate when the substrate is retained by the ESC.

In some implementations, the three or more regions may be oriented such that respective surfaces of the three or more regions along the first surface of the ceramic body can be at a different distance perpendicular to the surface of the substrate, where the supportive structures in each of the three or more regions can have corresponding heights to the respective distances of the three or more regions from the surface of the substrate.

In some embodiments, each of the three or more regions can include a different density of the supportive structures.

In some implementations, the process 800 further includes design parameters including (C) one or more heating elements (e.g., multiple heating zones, microheaters) arranged within the ceramic body, and/or (D) one or more electrodes within the ceramic body and arranged with respect to the first surface, e.g., chucking electrodes.

The system provides the predicted set of design parameters for fabricating the electrostatic chuck, e.g., to one or more manufacturing system for manufacturing the electrostatic chuck (808).

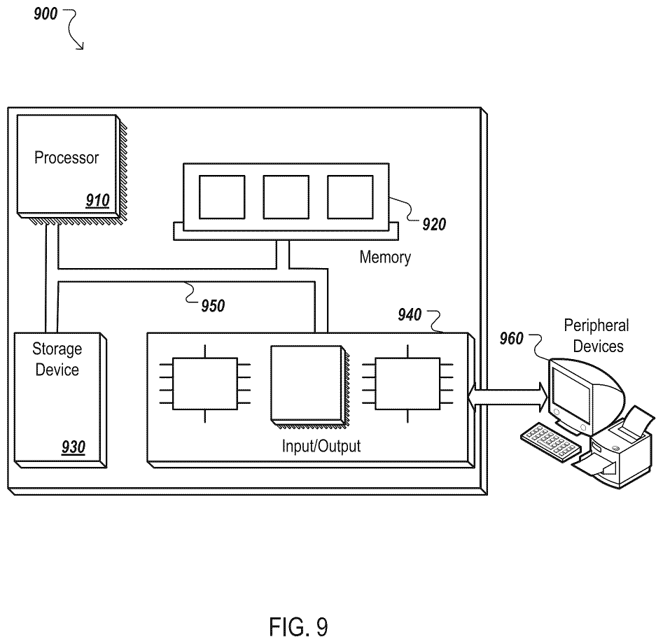

FIG. 9 is block diagram of an example computer system 900 that can be used to perform operations described above. For example, such as operations performed by the electrostatic chuck model. The system 900 includes a processor 910, a memory 920, a storage device 930, and an input/output device 940. Each of the components 910, 920, 930, and 940 can be interconnected, for example, using a system bus 950. The processor 910 is capable of processing instructions for execution within the system 900. In one implementation, the processor 910 is a single-threaded processor. In another implementation, the processor 910 is a multi-threaded processor. The processor 910 is capable of processing instructions stored in the memory 920 or on the storage device 930.

The memory 920 stores information within the system 900. In one implementation, the memory 920 is a computer-readable medium. In one implementation, the memory 920 is a volatile memory unit. In another implementation, the memory 920 is a non-volatile memory unit.

The storage device 930 is capable of providing mass storage for the system 900. In one implementation, the storage device 930 is a computer-readable medium. In various different implementations, the storage device 930 can include, for example, a hard disk device, an optical disk device, a storage device that is shared over a network by multiple computing devices (e.g., a cloud storage device), or some other large capacity storage device.

The input/output device 940 provides input/output operations for the system 900. In one implementation, the input/output device 940 can include one or more of a network interface device, e.g., an Ethernet card, a serial communication device, e.g., and RS-232 port, and/or a wireless interface device, e.g., and 802.11 card. In another implementation, the input/output device can include driver devices configured to receive input data and send output data to peripheral devices 960, e.g., keyboard, printer and display devices. Other implementations, however, can also be used, such as mobile computing devices, mobile communication devices, set-top box television client devices, etc.

Although an example processing system has been described in FIG. 9, implementations of the subject matter and the functional operations described in this specification can be implemented in other types of digital electronic circuitry, or in computer software, firmware, or hardware, including the structures disclosed in this specification and their structural equivalents, or in combinations of one or more of them.

Aspects of the subject matter and the actions and operations described in this specification, for example, computing devices such as controller 165 and processes performed by controller 165, can be implemented in digital electronic circuitry, in tangibly-embodied computer software or firmware, in computer hardware, including the structures disclosed in this specification and their structural equivalents, or in combinations of one or more of them. The subject matter and the actions and operations described in this specification can be implemented as or in one or more computer programs, e.g., one or more modules of computer program instructions, encoded on a computer program carrier, for execution by, or to control the operation of, data processing apparatus. The carrier can be a tangible non-transitory computer storage medium. Alternatively, or in addition, the carrier can be an artificially-generated propagated signal, e.g., a machine-generated electrical, optical, or electromagnetic signal, which is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

The term “data processing apparatus” encompasses all kinds of apparatus, devices, and machines for processing data, including by way of example a programmable processor, a computer, or multiple processors or computers. Data processing apparatus can include special-purpose logic circuitry, e.g., an FPGA (field programmable gate array), an ASIC (application-specific integrated circuit), or a GPU (graphics processing unit). The apparatus can also include, in addition to hardware, code that creates an execution environment for computer programs, e.g., code that constitutes processor firmware, a protocol stack, a database management system, an operating system, or a combination of one or more of them.

A computer program can be written in any form of programming language, including compiled or interpreted languages, or declarative or procedural languages; and it can be deployed in any form, including as a stand-alone program, e.g., as an app, or as a module, component, engine, subroutine, or other unit suitable for executing in a computing environment, which environment can include one or more computers interconnected by a data communication network in one or more locations.

A computer program can, but need not, correspond to a file in a file system. A computer program can be stored in a portion of a file that holds other programs or data, e.g., one or more scripts stored in a markup language document, in a single file dedicated to the program in question, or in multiple coordinated files, e.g., files that store one or more modules, sub-programs, or portions of code.

The processes and logic flows described in this specification can be performed by one or more computers executing one or more computer programs to perform operations by operating on input data and generating output. The processes and logic flows can also be performed by special-purpose logic circuitry, e.g., an FPGA, an ASIC, or a GPU, or by a combination of special-purpose logic circuitry and one or more programmed computers.

Computers suitable for the execution of a computer program can be based on general or special-purpose microprocessors or both, and any other kind of central processing unit. Generally, a central processing unit will receive instructions and data from a read-only memory or a random-access memory or both. The essential elements of a computer are a central processing unit for executing instructions and one or more memory devices for storing instructions and data. The central processing unit and the memory can be supplemented by, or incorporated in, special-purpose logic circuitry.

Generally, a computer will also include, or be operatively coupled to, one or more mass storage devices, and be configured to receive data from or transfer data to the mass storage devices. The mass storage devices can be, for example, magnetic, magneto-optical, or optical disks, or solid-state drives. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

To provide for interaction with a user, the subject matter described in this specification can be implemented on one or more computers having, or configured to communicate with, a display device, e.g., a LCD (liquid crystal display) monitor, or a virtual-reality (VR) or augmented-reality (AR) display, for displaying information to the user, and an input device by which the user can provide input to the computer, e.g., a keyboard and a pointing device, e.g., a mouse, a trackball or touchpad. Other kinds of devices can be used to provide for interaction with a user as well; for example, feedback and responses provided to the user can be any form of sensory feedback, e.g., visual, auditory, speech or tactile; and input from the user can be received in any form, including acoustic, speech, or tactile input, including touch motion or gestures, or kinetic motion or gestures or orientation motion or gestures. In addition, a computer can interact with a user by sending documents to and receiving documents from a device that is used by the user; for example, by sending web pages to a web browser on a user's device in response to requests received from the web browser, or by interacting with an app running on a user device, e.g., a smartphone or electronic tablet. Also, a computer can interact with a user by sending text messages or other forms of message to a personal device, e.g., a smartphone that is running a messaging application, and receiving responsive messages from the user in return.

This specification uses the term “configured to” in connection with systems, apparatus, and computer program components. That a system of one or more computers is configured to perform particular operations or actions means that the system has installed on it software, firmware, hardware, or a combination of them that in operation cause the system to perform the operations or actions. That one or more computer programs is configured to perform particular operations or actions means that the one or more programs include instructions that, when executed by data processing apparatus, cause the apparatus to perform the operations or actions. That special-purpose logic circuitry is configured to perform particular operations or actions means that the circuitry has electronic logic that performs the operations or actions.

While this specification contains many specific implementation details, these should not be construed as limitations on the scope of what is being claimed, which is defined by the claims themselves, but rather as descriptions of features that can be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features can be described above as acting in certain combinations and even initially be claimed as such, one or more features from a claimed combination can in some cases be excised from the combination, and the claim can be directed to a subcombination or variation of a subcombination.

Similarly, while operations are depicted in the drawings and recited in the claims in a particular order, this by itself should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

What is claimed is:

1. An electrostatic chuck (ESC) comprising:
a ceramic body comprising one or more embedded electrodes, the ceramic body comprising a first surface having a first diameter;
three or more regions defined on the first surface, wherein the three or more regions are arranged concentrically on the first surface, each region comprising:
a retaining ring arranged on the first surface and defining an outer edge of the region; and
a plurality of supportive structures arranged on the first surface and within the region, wherein the plurality of supportive structures is configured to support a surface of a substrate when the substrate is retained by the electrostatic chuck; and
a plurality of conduits formed in the ceramic body and configured to independently introduce a gas into each of the three or more regions through the ceramic body and to the first surface,
wherein each region of the three or more regions is configured to retain a corresponding positive gas pressure within the region and the surface of the substrate when the substrate is retained by the electrostatic chuck, and
wherein the one or more embedded electrodes are configured to generate a retaining force on the surface of the substrate when the substrate is retained by the electrostatic chuck.

2. The ESC of claim 1, further comprising one or more heating elements arranged within the ceramic body and configured to heat at least a portion of the surface of the substrate when the substrate is retained by the electrostatic chuck.

3. The ESC of claim 1, wherein each region of the three or more regions comprises a uniform density of the plurality of supportive structures.

4. The ESC of claim 3, wherein each region of the three or more regions comprises a different density of the plurality of supportive structures arranged within the region.

5. The ESC of claim 1, wherein at least one region of the three or more regions comprises a non-uniform density of the plurality of supportive structures.

6. The ESC of claim 5, wherein the non-uniform density of the plurality of supportive structures comprises a density gradient having a higher density adjacent to the retaining ring defining an outer edge of the region and a lower density at a center point of the region.

7. The ESC of claim 1, wherein at least one region of the three or more regions comprises mesas having a central tendency of height different than a central tendency of height for one or more other regions of the three or more regions.

8. The ESC of claim 1, further comprising a second surface and a third surface having respective second and third diameters, wherein each region of the three or more regions is defined on a respective surface.

9. The ESC of claim 1, wherein a density of the plurality of supportive structures within at least one region of the three or more regions is a threshold density for contact-dominated cooling.

10. The ESC of claim 1, wherein a density of the plurality of supportive structures within at least one region of the three or more regions is a threshold density for gas-dominated cooling.

11. The ESC of claim 1, wherein, when the substrate is retained by the ESC, the plurality of conduits is configured to independently introduce a different gas pressure into each of the three or more regions.

12. The ESC of claim 1, wherein an arrangement of the retaining ring and the plurality of supportive structures for each cooling region of the three or more regions is defined by parameters generated by a machine-learning model.

13. A method of cooling an electrostatic chuck during plasma processing comprising:
providing a gas through a plurality of conduits within a ceramic body of the electrostatic chuck to three or more regions defined on a first surface of the ceramic body and configured to retain a positive gas pressure within the region and a surface of a substrate retained by the electrostatic chuck,
wherein the three or more regions are arranged concentrically on the first surface, and
wherein an outer edge of each region of the three or more regions is defined by a respective retaining ring arranged on the first surface; and
providing by one or more electrodes within the ceramic body and arranged with respect to the first surface, a retaining force on the surface of the substrate.

14. The method of claim 13, wherein providing the gas through the plurality of conduits within the ceramic body of the electrostatic chuck to three or more regions defined on the first surface of the ceramic body comprises, providing a different gas pressure to each region of the three or more regions.

15. The method of claim 14, further comprising:
supporting the surface of the substrate by a plurality of supportive structures arranged on the first surface of the ceramic body and within at least one region of the three or more regions.

16. The method of claim 15, wherein supporting the surface of the substrate by a plurality of supportive structures arranged on the first surface of the ceramic body comprises, supporting the surface of the substrate by a different density of structures in at least one region of the three or more regions.

17. The method of claim 14, wherein providing the gas through conduits within the ceramic body of the electrostatic chuck to three or more regions defined between the first surface of the ceramic body and the surface of the substrate retained by the electrostatic chuck comprises cooling the surface of the substrate by contact-dominated cooling.

18. The method of claim 14, wherein providing the gas through conduits within the ceramic body of the electrostatic chuck to three or more regions defined between the first surface of the ceramic body and the surface of the substrate retained by the electrostatic chuck comprises cooling the surface of the substrate by gas-dominated cooling.

19. The method of claim 14, further comprising:
providing, by one or more heating elements arranged within the ceramic body, heating of the surface of the substrate.

20. A system comprising:
a plasma processing chamber enclosing a processing region;
a gas source configured to introduce one or more etch gases into the processing region;
a plasma source configured to generate a plasma within the processing region using the one or more etch gases introduced into the processing region; and
an electrostatic chuck within the plasma processing chamber and configured to retain a substrate in the processing region of the plasma processing chamber during plasma processing, the electrostatic chuck comprising:
a ceramic body comprising one or more embedded electrodes configured to generate a retaining force on a surface of the substrate when the substrate is retained by the electrostatic chuck;
three or more regions defined on a first surface of the ceramic body, wherein the three or more regions are arranging concentrically on the first surface, each region comprising a retaining ring arranged on the first surface and defining an outer edge of the region; and
a plurality of conduits formed in the ceramic body and configured to independently introduce a gas into each of the three or more regions through the ceramic body and to the first surface.
